(19) United States
(12) Patent Application Publication
(10) Pub. No.: US 2023/0067973 A1
(43) Pub. Date: Mar. 2, 2023

(54) APPARATUS FOR TREATING SUBSTRATE AND METHOD FOR TREATING A SUBSTRATE

(71) Applicant: SEMES CO., LTD., Cheonan-si (KR)

(72) Inventors: Tae Hee KIM, Yongin-si (KR); Ki Hoon CHOI, Cheonan-si (KR); Hyun YOON, Hwaseong-si (KR); Won Sik SON, Yongin-si (KR); Hyo Won YANG, Seoul (KR); In Ki JUNG, Hwaseong-si (KR)

(73) Assignee: SEMES CO., LTD., Cheonan-si (KR)

(21) Appl. No.: 17/901,941

(22) Filed: Sep. 2, 2022

(30) Foreign Application Priority Data
Sep. 2, 2021 (KR) 10-2021-0116913

(51) Int. Cl. G03F 1/66; B08B 3/02; B08B 13/00; G03F 1/60

(52) U.S. Cl. CPC G03F 1/66; B08B 3/022; B08B 13/00; G03F 1/60

(57) ABSTRACT

The inventive concept provides a mask treating apparatus. The mask treating apparatus includes a support unit configured to support and rotate a mask, the mask having a first pattern within a plurality of cells thereof and a second pattern outside regions of the plurality of cells; and a heating unit having a laser irradiator for irradiating a laser light to a specific region of the mask supported on the support unit, and a controller configured to control the support unit and the heating unit, and wherein the support unit includes: a support part for supporting the mask; and a moving stage part configured to move a position of the support part, and wherein the controller controls the moving stage part so a position of the mask supported on the support part is changed so the second pattern is positioned at the specific region.

### CROSS-REFERENCE TO RELATED APPLICATIONS

A claim for priority under 35 U.S.C. § 119 is made to Korean Patent Application No. 10-2021-0116913 filed on Sep. 2, 2021, in the Korean Intellectual Property Office, the entire contents of which are hereby incorporated by reference.

### BACKGROUND

Embodiments of the inventive concept described herein relate to a substrate treating apparatus and a substrate treating method, more specifically, a substrate treating apparatus and a substrate treating method for treating a substrate by heating the substrate.

In order to manufacture a semiconductor element, various processes such as a photolithography process, an etching process, an ashing process, an ion implantation process, and a thin film deposition process are performed on a substrate such as a wafer. Various treating liquids and treatment gases are used in each process. In addition, a drying process is performed on the substrate to remove a treating liquid used to treat the substrate from the substrate.

The photolithography process for forming a pattern on the wafer includes an exposing process. The exposing process is an operation which is previously performed for cutting a semiconductor integrated material attached to the wafer into a desired pattern. The exposing process may have various purposes such as forming a pattern for an etching and forming a pattern for the ion implantation. In the exposing process, the pattern is drawn in on the wafer with a light using a mask, which is a kind of ‘frame’. When the light is exposed to the semiconductor integrated material on the wafer, for example, a resist on the wafer, chemical properties of the resist change according to a pattern by the light and the mask. When a developing liquid is supplied to a resist which chemical properties have changed according to the pattern, the pattern is formed on the wafer.

In order to precisely perform the exposing process, the pattern formed on the mask must be precisely manufactured. To confirm that the pattern is formed in a desired form and precisely, an operator inspects a formed pattern using an inspection equipment such as a scanning electron microscope (SEM). However, a large number of patterns are formed on one mask. That is, it takes a lot of time to inspect all of the large number of patterns to inspect one mask.

Accordingly, a monitoring pattern capable of representing one pattern group including a plurality of patterns is formed on the mask. In addition, an anchor pattern that may represent a plurality of pattern groups are formed on the mask. The operator may estimate whether patterns formed on the mask are good or not through an inspecting of the anchor pattern. In addition, the operator may estimate whether patterns included in one pattern group are good or not through an inspecting of the monitoring pattern.

As described above, the operator may effectively shorten a time required for a mask inspection due to the monitoring pattern and the anchor pattern formed on the mask. However, in order to increase an accuracy of the mask inspection, it is preferable that critical dimension of the monitoring pattern and the anchor pattern are the same.

When an etching is performed to equalize the critical dimension of the monitoring pattern and the critical dimension of the anchor pattern, an over-etching may occur at the pattern. For example, a difference between an etching rate for the critical dimension of the monitoring pattern and an etching rate for the anchor pattern may occur several times, and in the process of repeatedly etching the monitoring pattern and/or the anchor pattern to reduce the difference, the over-etching may occur at the critical dimension of the monitoring pattern and the critical dimension of the anchor pattern. When the etching process is precisely performed to minimize an occurrence of such over-etching, the etching process takes a lot of time. Accordingly, a critical dimension correction process for precisely correcting the critical dimension of patterns formed on the mask is additionally performed.

FIG. 1 illustrates a normal distribution regarding a first critical dimension CDP1 of the monitoring pattern of the mask and a second critical dimension CDP2 (a critical dimension of the anchor pattern) before a critical dimension correction process is performed during a mask manufacturing process. In addition, the first critical dimension CDP1 and the second critical dimension CDP2 have a size smaller than a target critical dimension. Before the critical dimension correction process is performed, there is a deliberate deviation between the critical dimension of the monitoring pattern and the anchor pattern (CD, critical dimension). And, by additionally etching the anchor pattern in the critical dimension correction process, the critical dimension of these two patterns are made the same. In the process of over-etching the anchor pattern, if the anchor pattern is more over-etched than the monitoring pattern, a difference in the critical dimension of the monitoring pattern and the anchor pattern occurs, and thus the critical dimension of the patterns formed at the mask may not be accurately corrected. When additionally etching the anchor pattern, a precise etching with respect to the anchor pattern should be accompanied.

### SUMMARY

Embodiments of the inventive concept provide a substrate treating apparatus and a substrate treating method for efficiently treating a substrate.

Embodiments of the inventive concept provide a substrate treating apparatus and a substrate treating method for making a critical dimension of a pattern formed on a substrate uniform.

Embodiments of the inventive concept provide a substrate treating apparatus and a substrate treating method for performing a precise etching with respect to a specific pattern formed on a substrate.

The technical objectives of the inventive concept are not limited to the above-mentioned ones, and the other unmentioned technical objects will become apparent to those skilled in the art from the following description.

The inventive concept provides a mask treating apparatus. The mask treating apparatus includes: a support unit configured to support and rotate a mask, the mask having a first pattern within a plurality of cells thereof and a second pattern outside regions of the plurality of cells; and a heating unit having a laser irradiator for irradiating a laser light to a specific region of the mask supported on the support unit, and a controller configured to control the support unit and the heating unit, and wherein the support unit includes: a support part for supporting the mask; and a moving stage part configured to move a position of the support part, and wherein the controller controls the moving stage part so a position of the mask supported on the support part is changed so the second pattern is positioned at the specific region.

In an embodiment, the support unit further comprises a rotation part configured to rotate the moving stage part, and wherein the controller controls the rotation part so the mask stop rotation while the laser light is being irradiated by the laser irradiator to the second pattern.

In an embodiment, the mask treating apparatus includes a liquid supply unit configured to supply a treating liquid to the mask supported on the support unit, and wherein the controller controls the rotation part so the mask is rotated while the liquid supply unit is supplying the treating liquid to the mask.

In an embodiment, the moving stage part includes: a base positioned below the support part; a first driving part installed at the base and moving the support part in a first direction which is horizontal to the ground; and a second driving part installed at the base and moving the support part in a second direction which is orthogonal to the first direction and horizontal to the ground.

In an embodiment, the mask treating apparatus further includes a container having a treating space for treating the mask and a recollecting path for recollecting the treating liquid, and wherein the support unit supports the substrate at the treating space.

In an embodiment, a position of the laser irradiator is fixed while the laser irradiator irradiates the laser light.

In an embodiment, a process for minimizing a deviation between a critical dimension of the first pattern and a critical dimension of the second pattern by irradiating the laser light with respect to the second pattern is performed.

In an embodiment, regarding a first pattern and a second pattern provided at each cell, the first pattern is a monitoring pattern of an exposing pattern formed at a cell and the second pattern is a condition setting pattern of the mask treating apparatus.

The inventive concept provides a substrate treating apparatus. The substrate treating apparatus includes: a support unit configured to support and rotate a substrate at which a pattern is formed; a heating unit configured to heat a specific region of the substrate; a controller configured to control the support unit and the heating unit, and wherein the support unit includes: a support part for supporting the substrate; and a moving stage part configured to change a position of the support part, and wherein the controller controls the moving state unit so a position of the substrate supported on the support unit is changed so a specific pattern among the pattern is positioned at the specific region.

In an embodiment, the support unit further comprises a rotation part configured to rotate the moving stage part, and wherein the controller controls the rotation part so the substrate does not rotate while the heating unit heats the specific pattern.

In an embodiment, the substrate treating apparatus further includes a liquid supply unit for supplying a treating liquid to the substrate supported on the support unit, and wherein the controller controls the rotation part so the substrate is rotated while the liquid supply unit is supplying the treating liquid to the substrate.

In an embodiment, the moving stage part includes: a base positioned below the support part; a first driving part installed at the base and moving the support part in a first direction which is horizontal to the ground; and a second driving part installed at the base and moving the support part in a second direction which is orthogonal to the first direction and horizontal to the ground.

In an embodiment, the heating unit includes a laser irradiator irradiating a laser light to the specific pattern, and a position of the laser irradiator is fixed while the laser irradiator irradiates the laser light.

In an embodiment, a process for minimizing a deviation between a critical dimension of the specific pattern and a critical dimension of a pattern aside from the specific pattern by irradiating the laser light with respect to the specific pattern is performed.

In an embodiment, the specific pattern is a condition setting pattern of the substrate treating apparatus.

The inventive concept provides a substrate treating method for etching a substrate having a first pattern and a second pattern which is different from the first pattern formed thereon. The substrate treating method includes: taking in the substrate and supporting the substrate on a support unit, which is a substrate taking-in step; moving a position of the substrate supported on the support unit so the support unit is moved so the second pattern is positioned at a specific region, which is a position correcting step; supplying a treating liquid to the substrate supported on the support unit, which is a liquid treating step; and irradiating a laser light to the second pattern at the specific region from a laser irradiator provided above the specific region.

In an embodiment, the substrate is rotated at the liquid treating step.

In an embodiment, a rotation of the substrate is stopped at the heating step.

In an embodiment, a position of the laser irradiator is fixed while the laser irradiator irradiates the laser light.

In an embodiment, a deviation between a critical dimension of the first pattern and a critical dimension of the second pattern by irradiating the laser light with respect to the second pattern is minimized.

According to an embodiment of the inventive concept, a substrate may be efficiently treated.

According to an embodiment of the inventive concept, a critical dimension of a pattern formed on a substrate may be made uniform.

According to an embodiment of the inventive concept, a precise etching with respect to a specific pattern formed on a substrate.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a normal distribution of a critical dimension of a monitoring pattern and a critical dimension of an anchor pattern.

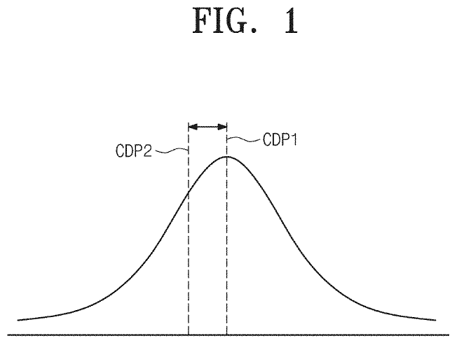

FIG. 2 is a plan view schematically illustrating a substrate treating apparatus according to an embodiment of the inventive concept.

FIG. 3 schematically illustrates a state of a substrate treated at a liquid treating chamber of FIG. 2.

FIG. 4 schematically illustrates an embodiment of the liquid treating chamber of FIG. 2.

FIG. 5 is a top view of a moving stage of FIG. 4.

FIG. 6 is a top view of a support unit moving at the liquid treating chamber of FIG. 4.

FIG. 7 illustrates a body, a laser module, an image module and an optical module of a heating unit of FIG. 4.

FIG. 8 is a top view of the image module of FIG. 7.

FIG. 9 schematically illustrates another embodiment of the liquid treating chamber of FIG. 2.

FIG. 10 and FIG. 11 schematically illustrate a state of irradiating a light to the substrate at a heating unit of FIG. 9.

FIG. 12 is a flowchart of a substrate treating method according to an embodiment of the inventive concept.

FIG. 13 illustrates a state of the substrate treating apparatus for performing a process preparing step of FIG. 12.

FIG. 14 illustrates a state of the substrate treating apparatus for performing the position correcting step of FIG. 12.

FIG. 15 illustrates a state of the substrate treating apparatus for performing a liquid treating step of FIG. 12.

FIG. 16 illustrates a state of the substrate treating apparatus in which a liquid supply is completed at the liquid treating step of FIG. 12.

FIG. 17 illustrates a state of the substrate treating apparatus for performing a heating step of FIG. 12.

FIG. 18 illustrates a state of the substrate treating apparatus for performing a rinsing step of FIG. 12.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Hereinafter, embodiments of the inventive concept will be described in detail with reference to the accompanying drawings.

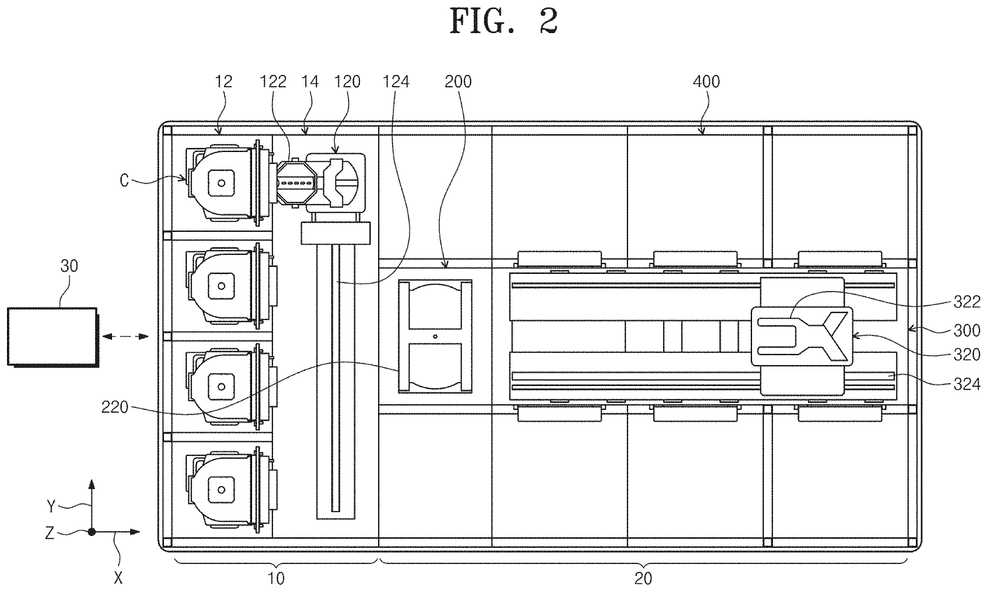

Hereinafter, an embodiment of the inventive concept will be described in detail with reference to FIG. 2 to FIG. 18. FIG. 2 is a plan view schematically illustrating a substrate treating apparatus according to an embodiment of the inventive concept. Referring to FIG. 2, the substrate treating apparatus includes an index module 10, a treating module 20, and a controller 30. According to an embodiment, when viewed from above, the index module 10 and the treating module 20 may be disposed along a direction. Hereinafter, a direction in which the index module 10 and the treating module 20 are disposed is defined as a first direction X, a direction perpendicular to the first direction X when viewed from above is defined as a second direction Y, and a direction perpendicular to a plane including both the first direction X and the second direction Y is defined as a third direction Z.

The index module 10 transfers a substrate M from a container C in which the substrate M is accommodated to the treating module 20 for treating the substrate M. The index module 10 stores a substrate M on which a predetermined treatment has been completed at the treating module 20 in the container C. A lengthwise direction of the index module 10 may be formed in the second direction Y. The index module 10 may have a load port 12 and an index frame 14.

The container C in which the substrate M is accommodated is seated on the load port 12. The load port 12 may be positioned on an opposite side of the treating module 20 with respect to the index frame 14. A plurality of load ports 12 may be provided, and the plurality of load ports 12 may be arranged in a line along the second direction Y. The number of load ports 12 may increase or decrease according to a process efficiency and foot print conditions, etc of the treating module 20.

As the container C, a sealing container such as a front opening unified pod (FOUP) may be used. The container C may be placed on the load port 12 by a transfer means (not shown) such as an overhead transfer, an overhead conveyor, or an automatic guided vehicle, or by an operator.

An index robot 120 and an index rail 124 may be provided at the index frame 14. The index robot 120 transfers the substrate M. The index robot 120 may transfer the substrate M between the index module 10 and the buffer unit 200 to be described later. The index robot 120 includes an index hand 122 on which the substrate M is placed. The substrate M may be placed on the index hand 122. The index hand 122 may be provided to be forwardly and backwardly movable, rotatable in the third direction Z, and movable along the third direction Z. A plurality of hands 122 may be provided to be spaced apart from each other in an up/down direction. The plurality of hands 122 may be forwardly and backwardly movable independently of each other.

The index rail 124 is provided in the index frame 14 with its lengthwise direction along the second direction Y. The index robot 120 may be placed on the index rail 124, and the index robot 120 may be movable along the index rail 124.

The controller 30 may control a substrate treating apparatus. The controller may comprise a process controller consisting of a microprocessor (computer) that executes a control of the substrate treating apparatus, a user interface such as a keyboard via which an operator inputs commands to manage the substrate treating apparatus, and a display showing the operation situation of the substrate treating apparatus, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The treating module 20 may include a buffer unit 200, a transfer chamber 300, and a liquid treating chamber 400. The buffer unit 200 provides a space in which a substrate M taken into the treating module 20 and a substrate M taken out of the treating module 20 temporarily remain. The transfer chamber 300 provides a space for transferring the substrate M between the buffer unit 200, the liquid treating chamber 400, and the drying chamber 500. The liquid treating chamber 400 supplies a liquid onto the substrate M to perform a liquid treatment process for treating the substrate M.

The buffer unit 200 may be disposed between the index frame 14 and the transfer chamber 300. The buffer unit 200 may be positioned at an end of the transfer chamber 300. A slot (not shown) in which the substrate M is placed is provided inside the buffer unit 200. A plurality of slots (not shown) may be provided to be spaced apart from each other in the third direction Z.

A front face and a rear face of the buffer unit 200 are opened. The front face is a surface facing the index module 10, and the rear face is a surface facing the transfer chamber 300. The index robot 120 may approach the buffer unit 200 through the front face, and the transfer robot 320 to be described later may approach the buffer unit 200 through the rear face.

The transfer chamber 300 may have a lengthwise direction provided in the first direction X. The liquid treating chamber 400 and the drying chamber 500 may be disposed on both sides of the transfer chamber 300. The liquid treating chamber 400 and the drying chamber 500 may be disposed at a side of the transfer chamber 300. The transfer chamber 300 and the liquid treating chamber 400 may be disposed along the second direction Y. The transfer chamber 300 and the drying chamber 500 may be disposed along the second direction Y.

According to an embodiment, liquid treating chambers 400 may be disposed on both sides of the transfer chamber 300. The liquid treating chambers 400 may be provided in an arrangement of AX B (where A and B are natural numbers greater than 1 or 1 respectively) along the first direction X and the third direction Z respectively at aside of the transfer chamber 300.

The transfer chamber 300 includes a transfer robot 320 and a transfer rail 340. The transfer robot 320 transfers the substrate M. The transfer robot 320 transfers the substrate M between the buffer unit 200, the liquid treating chamber 400, and the drying chamber 500. The transfer robot 320 includes a transfer hand 322 on which the substrate M is placed. The substrate M may be placed on the transfer hand 322. The transfer hand 322 may be provided to be forwardly and backwardly movable, to be rotatable around the third direction Z, and movable along the third direction Z. A plurality of hands 322 are provided to be spaced apart from each other in the up/down direction, and the plurality of hands 322 may be forwardly and backwardly movable independently of each other.

The transfer rail 340 may be provided in the transfer chamber 300 along a lengthwise direction of the transfer chamber 300. In an embodiment, the lengthwise direction of the transfer rail 340 may be provided along the first direction X. The transfer robot 320 may be placed on the transfer rail 340 and the transfer robot 320 may be movable on the transfer rail 340.

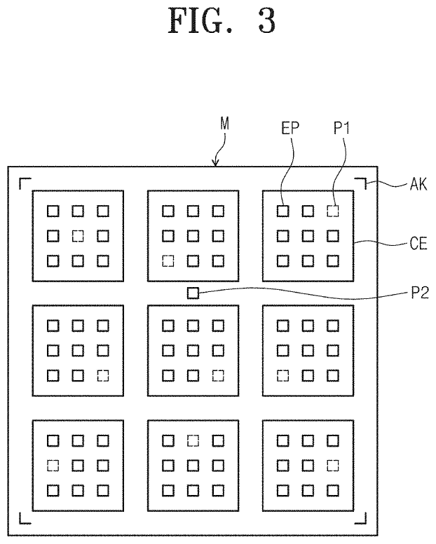

Hereinafter, a substrate M treated in the liquid treating chamber 400 will be described in detail. FIG. 3 schematically illustrates a state of the substrate treated in the liquid treating chamber of FIG. 2.

Referring to FIG. 3, an object to be treated in the liquid treating chamber 400 may be any one of a wafer, a glass, and a photomask. For example, the substrate M treated in the liquid treating chamber 400 may be a photo mask, which is a ‘frame’ used in an exposing process.

The substrate M may have a rectangular form. The substrate M may be a photo mask that is a ‘frame’ used in the exposing process. At least one reference mark AK may be marked on the substrate M. For example, a plurality of reference marks AK may be formed in each corner region of the substrate M. The reference mark AK may be a mark called an align key used when aligning the substrate M. Also, the reference mark AK may be a mark used to derive a position of the substrate M. For example, an image module 470 to be described later may acquire an image by imaging the reference mark AK and transmit the acquired image to the controller 30. The controller 30 then may analyze the image including the reference mark AK to detect an accurate position of the substrate M. In addition, the reference mark AK may be used to determine a position of the substrate M when the substrate M is transferred.

A cell CE may be formed on the substrate M. At least one cell CE, for example, a plurality of cells CE may be formed. A plurality of patterns may be formed at each cell CE. The patterns formed at each cell CE may be defined as one pattern group. Patterns formed at the cell CE may include an exposing pattern EP and a first pattern P1. A second pattern P2 may be proved in a region outside the cell region where the plurality of cells care formed.

The exposing pattern EP may be used to form an actual pattern on the substrate M. The first pattern P1 may be a single-cell representative pattern representing exposing patterns EP in one cell CE. In addition, when the plurality of cells CE are provided, the first pattern is provided in each cell, thereby a plurality of first patterns P1 may be provided. In an embodiment, each of the plurality of cells CE may be provided with single first pattern P1. However, the inventive concept is not limited thereto, and the plurality of first patterns P1 may be formed in one cell CE. The first pattern P1 may have a form in which portions of each exposing pattern EP are combined.

The first pattern P1 may be referred to as a monitoring pattern. An average value of critical dimension of the plurality of first patterns P1 may be referred to as a critical dimension monitoring macro.

When an operator inspects the first pattern P1 through a scanning electron microscope (SEM), it is possible to estimate whether a form of the exposing patterns EPs formed in one cell CE are good or bad. Accordingly, the first pattern P1 may serve as an inspection pattern to inspect the exposing patters EPs. Also, unlike the above-described example, the first pattern P1 may be any one of the exposing patterns EPs used in an actual exposing process. In addition, the first pattern P1 may be serve as not only inspection pattern to inspect the exposing patterns but also exposing pattern used in the actual exposing.

The second pattern P2 may be an entire-cell representative pattern representing exposing patterns EP on whole cells of the substrate M. For example, the second pattern P2 may have a form in which portions of each of the first patterns P1 are combined.

When the operator inspects the second pattern P2 through the scanning electron microscope (SEM), it is possible to estimate whether a form of the exposing patterns EPs formed on one substrate M are good or bad. Accordingly, the second pattern P2 may serve an inspection pattern. In addition, the second pattern P2 may be an inspection pattern that is not used in an actual exposing process. The second pattern P2 may be a pattern for setting a process condition of an exposing apparatus. The second pattern P2 may be referred to as an anchor pattern. The second pattern P2 may be provided at an outside of a region at which the cells CE are formed.

Hereinafter, the substrate treating apparatus provided to the liquid treating chamber 400 will be described in detail. Hereinafter, a treating process performed while the liquid treating chamber 400 performs a fine critical dimension correction (FCC) process during a process of manufacturing a mask for an exposing process will be described as an example.

A substrate M to be taken in and treated at the liquid treating chamber 400 may be a substrate M on which a pre-treatment has been performed. A critical dimension of the first pattern P1 and a critical dimension of the second pattern P2 of the substrate M to be taken into the liquid treating chamber 400 may be different from each other. For example, the critical dimension of the first pattern P1 may be greater than the critical dimension of the second pattern P2. In on embodiment, the critical dimension of the first pattern P1 may have a first width (e.g., 69 nm). The critical dimension of the second pattern P2 may have a second width (e.g., 68.5 nm).

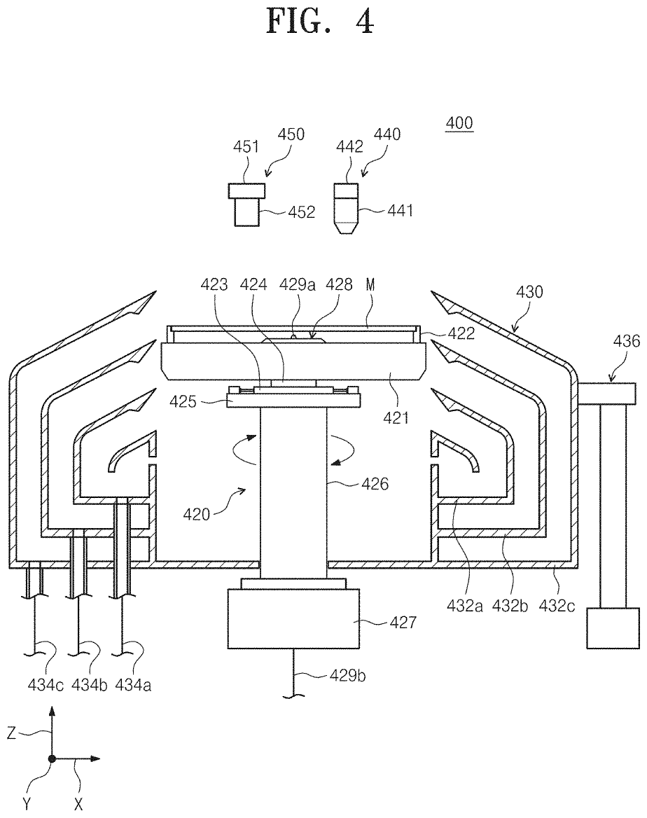

FIG. 4 schematically illustrates an embodiment of the liquid treating chamber of FIG. 2. Referring to FIG. 4, the liquid treating chamber 400 may include a housing (not shown), a support unit 420, a treating container 430, a liquid supply unit 440, and a heating unit 450.

The housing (not shown) has an inner space. The housing (not shown) may have an inner space provided with a treating container 430. The housing (not shown) may have an inner space in which the liquid supply unit 440 and the heating unit 450 are provided. The housing (not shown) may be provided with a gateway (not shown) through which the substrate M may be taken in and taken out. An inner wall surface of the housing (not shown) may be coated with a material having a high corrosion resistance to a chemical supplied by the liquid supply unit 440.

An exhaust hole (not shown) may be formed on a bottom surface of the housing (not shown). The exhaust hole (not shown) may be connected to an exhaust member such as a pump capable of exhausting an inner space. Accordingly, a fume or the like that may be generated at the inner space may be exhausted to an outside of the housing (not shown) through the exhaust hole (not shown).

The support unit 420 may support the substrate M. The support unit 420 may rotate the substrate M. The support unit may support and rotate the substrate M at the treating space included at the treating container 430 to be described later. The support unit 420 may include a chuck 421, a support pin 422, a first driving unit 423, a second driving unit 424, a support shaft 426, and a driving member 427.

Hereinafter, the chuck 421 and the support pin 422 are included and defined as a support part. The support part supports the substrate M. In an embodiment, the support part may support the substrate M at which a first pattern P1 is formed in a plurality of cells CE and a second pattern P2 is formed outside a region in which the cells CE are formed.

The chuck 421 may have a plate form having a constant thickness. The chuck 421 may have a top surface provided in a generally circular form when viewed from above. The top surface of the chuck 421 may be provided to have a region larger than that of the substrate M. The support pin 422 may be installed on the chuck 421.

The support pin 422 may support the substrate M. A plurality of support pins 422 are provide along a circumferential direction of the top side chuck 421, thereby viewed from above, the support pins 422 may have a substantially circular form. When viewed from above, the support pin 422 may have a stepped portion to support the substrate M. The stepped portion of the support pin 422 may have a first surface (bottom surface) and a second surface(side surface). In an embodiment, the first surface may support back-side (bottom side) surface at edge region of the substrate M. The second surface may support side surface of the substrate M so as to limit a lateral movement of the substrate M when the substrate M is rotated. At least one support pin 422 may be provided. In an embodiment, a plurality of support pins 422 may be provided. The support pins 422 may be provided in a number corresponding to the number of corners of the substrate M having a rectangular form. The support pin 422 may support the back-side(bottom surface) of the substrate

M to be spaced apart from a top surface of the chuck 421.

The first driving unit 423, the second driving unit 424, and a base 425 may be positioned below the chuck 421. Hereinafter, the first driving unit 423, the second driving unit 424, and the base 425 are included to define a moving stage part. The moving stage part moves a position of the support unit. In an embodiment, the moving stage part may move the support unit in a first direction X and a second direction Y. The moving stage part may move the chuck 421 in a first direction X and a second direction Y.

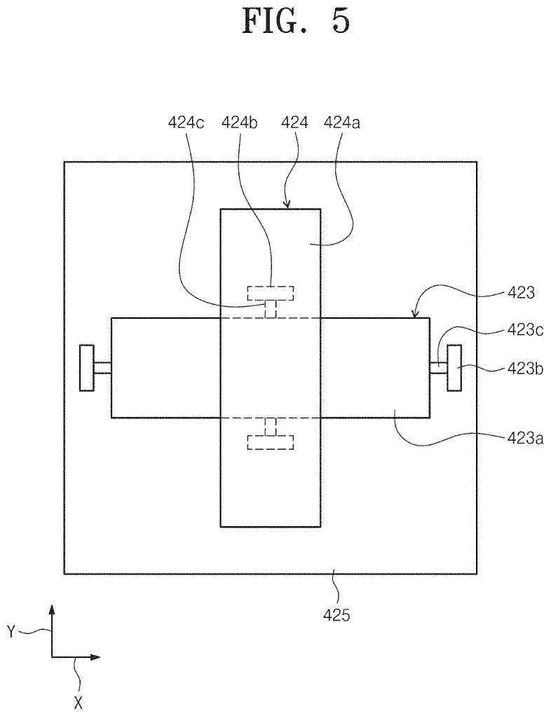

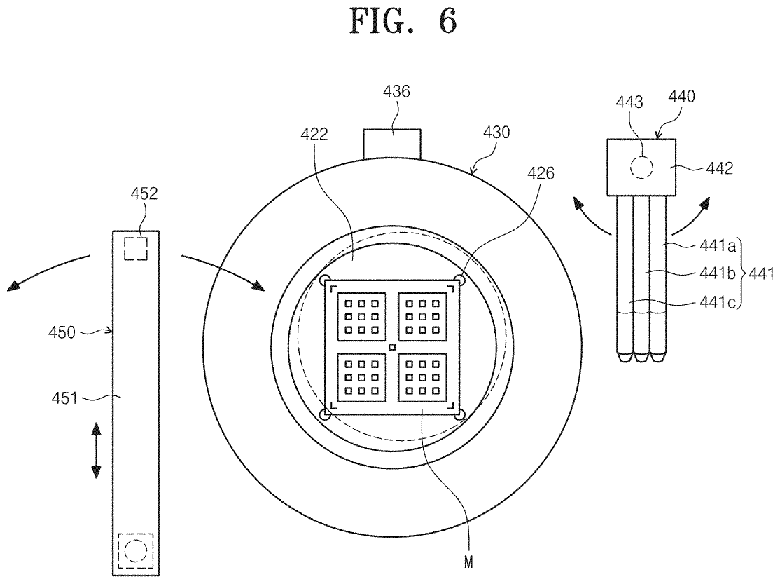

FIG. 5 is a view of a moving stage of FIG. 4 when seen from above. FIG. 6 is a view of a support unit moving at a liquid treating chamber of FIG. 4 when seen from above. Referring to FIG. 5 and FIG. 6, a first moving unit 423 may be installed at a base 425 to be explained later. The first driving unit 423 may be installed above the base 425. The first driving unit may be installed between the base 425 and a second driving unit 424 to be explained later. The first driving unit 423 may move the support unit. For example, the first driving unit 423 may move the support unit in the first direction X. The first driving unit 423 may be configured of a first body 423a, a first driver 423b, and a first guide rail 423c.

The first body 423a may be installed on the base 425. The first body 423a may be positioned on the first guide rail 423c. The first body 423a may move along a lengthwise direction of the first guide rail 423c. The first body 423c may move in the first direction X. The first body 423c may move the second body 424b to be explained later in the first direction X.

The first driver 423b may be provided as any one of known devices for generating a power, such as a motor for generating a driving force, a pneumatic cylinder, a hydraulic cylinder, or a solenoid. The first driver 423b may generate the driving force to move the first body 423a in the lengthwise direction of the first guide rail 423c. The first guide rail 423c may be installed above the base 425. The first guide rail 423c may be installed on a top surface of the base. The lengthwise direction of the first guide rail 423c may be formed along the first direction X.

Unlike the above-described example, the first driving unit 423 may include a first body 423a, a first driver 423b, and a first shaft (not shown). The first shaft (not shown) may be coupled to the first body 423a to receive a driving force generated by the first driver 423b to move the first body 423a in the first direction X.

The second driving unit 424 may be installed on a base 425 to be described later. The second driving unit 424 may be installed above the first driving unit 423. The base 425, the first driving unit 423, and the second driving unit 424 may be sequentially installed in a direction away from the ground. The second driving unit 424 may move the support unit. For example, the second driving unit 424 may move the support unit in the second direction Y. The second driver 424 may include a second body 424a, a second driver 424b, and a second guide rail 424c.

The second body 424a may be positioned on the first body 423a. The second body 424a may be positioned on the second guide rail 424c. The second body 424a may move along a lengthwise direction of the second guide rail 424c. According to an embodiment, the second body 424a may be fixed to a chuck 421. For example, a top surface of the second body 424a may be coupled to a bottom surface of the chuck 421.

The second body 424a may move in the second direction Y. The second driver 424b may transmit a driving force to the second body 424a. The second driver 424b may generate the driving force to move the second body 424a in the lengthwise direction of the second guide rail 424c. Since the second driver 424b has a similar structure and form to the first driver 423b described above, a description of the overlapping contents thereof will be omitted. The second guide rail 424c may be installed above the first body 423a. The second guide rail 424c may be installed on a top surface of the first body 423a. The lengthwise direction of the second guide rail 424c may be formed along the second direction Y.

Unlike the above-described example, the second driver 424 may include a second body 424a, a second driver 424b, and a second shaft (not shown). The second shaft (not shown) may be coupled to the second body 424a to receive a driving force generated by the second driver 424b to move the second body 424a in the second direction Y.

The base 425 may be positioned below the chuck 421. The base 425 may be positioned on a top portion of a support shaft 426 to be described later. The base 425 may be positioned between the chuck 421 and the support shaft 426. A first driving unit 423 and a second driving unit 424 may be installed on the base 425. A first guide rail 423c may be installed on a top surface of the base 425.

Referring back to FIG. 4, a support shaft 426 and a driving member 427 may be positioned below the chuck 421. The support shaft 426 and the driving member 427 may be positioned below the moving stage part. Hereinafter, the support shaft 426 and the driving member 427 are included and defined as a rotation part. The rotation part may rotate a moving stage unit. The rotation part may rotate the base 425.

The support shaft 426 may be a hollow shaft. The support shaft 426 may be rotated by the driving member 427. The driving member 427 may be a hollow motor. When the driving member 427 rotates the support shaft 426, the base 425 coupled to the support shaft 426 may rotate. As the base 425 is rotated, the first driving unit 423 coupled to the base 425 and the second driving unit 424 coupled to the first driving unit 423 may rotate, and the chuck 421 coupled to the second driving unit 424 may rotate. A substrate M placed on the support pin 422 installed on the chuck 421 may be rotated together with a rotation of the chuck 421.

The treating container 430 has a treating space with an open top. The treating container 430 may have a cylindrical form with an open top. The substrate M may be liquid-treated and heat-treated in the treating space. The treating container 430 can prevent the treating liquid supplied to the substrate M from being scattered to the housing (not shown), the liquid supply unit 440, and the heating unit 450.

The treating container 430 may have a plurality of recollecting containers 432a, 432b, and 432c. Each of the recollecting containers 432a, 432b, and 432c may separately recollect different liquids from each other among liquids used for treating the substrate M. Each of the recollecting containers 432a, 432b, and 432c may have a recollecting space for recollecting a liquid used for treating the substrate M. Each of the recollecting containers 432a, 432b, and 432c may be provided in an annular ring form surrounding the support unit 420. When the liquid treatment process is performed, a liquid scattered by a rotation of the substrate M is introduced into the recollecting space through an inlet, which is a space formed between the recollecting containers 432a, 432b, and 432c, respectively. The different types of treating liquids may be introduced into each of the recollecting containers 432a, 432b, and 432c.

According to an embodiment, the treating container 430 may have a first recollecting container 432a, a second recollecting container 432b, and a third recollecting container 432c. The first recollecting container 432a may be provided in an annular ring form surrounding the support unit 420. The second recollecting container 432b may be provided in an annular ring form surrounding the first recollecting container 432a. The third recollecting container 432c may be provided in an annular ring form surrounding the second recollecting container 432b.

To each of the recollecting containers 432a, 432b, 432c, recollecting lines 434a, 434b, 434c extending vertically in a bottom direction of a respective bottom surface can be connected. Each of the recollecting lines 434a, 434b, 434c may discharge a treating liquid introduced through each of the recollecting containers 432a, 432b, 432c. A discharged treating liquid may be reused through an outer treating liquid regeneration system (not shown).

The treating container 430 may be coupled to a lifting/lowering member 436. The lifting/lowering member 436 may change a position of the treating container 430 along the third direction Z. The lifting/lowering member 436 may be a driving device for moving the treating container 430 in the up/down direction. The lifting/lowering member 436 may move the treating container 430 in an upward direction while a liquid treatment and/or a heat treatment are performed on the substrate M. The lifting/lowering member 436 may move the treating container 430 in a downward direction when the substrate M is taken into an inner space of the housing (not shown) or the substrate M is taken out of the inner space of the housing (not shown).

The liquid supply unit 440 may supply a liquid to the substrate M. The liquid supply unit 440 may supply a treating liquid for liquid treating the substrate M. The liquid supply unit 440 may supply the treating liquid to a substrate M supported by the support unit 420. In an embodiment, the liquid supply unit 440 may supply the treating liquid to a substrate M having a first pattern formed within a plurality of cells CE and a second pattern P2 formed outside a region at which the cells CE are formed.

The treating liquid may be an etching liquid or a rinsing liquid. The etching liquid may be a chemical. The etching liquid may etch a pattern formed on the substrate M. The etching liquid may also be referred to as an etching liquid. The etching liquid may be a liquid containing a mixed solution in which an ammonia, a water, and additives are mixed and a hydrogen peroxide is included. The rinsing liquid may clean the substrate M. The rinsing liquid may be provided as a known chemical liquid.

Referring to FIG. 6, the liquid supply unit 440 may include a nozzle 441, a fixing body 442, a rotation shaft 443, and a rotation member 444. The nozzle 441 may supply the treating liquid to the substrate M supported by the support unit 420. An end of the nozzle 441 may be connected to the fixing body 442, and another end thereof may extend in a direction from the fixing body 442 toward the substrate M. The nozzle 411 may extend from the fixing body 442 in the first direction X.

The nozzle 411 may include a first nozzle 411a, a second nozzle 411b, and a third nozzle 411c. Any one of the first nozzle 411a, the second nozzle 411b, or the third nozzle 411c may supply a chemical C among the above-described treating liquids. In addition, another one of the first nozzle 411a, the second nozzle 411b, and the third nozzle 411c may supply the rinsing liquid R among the aforementioned treating liquids. The last one of the first nozzle 411a, the second nozzle 411b, or the third nozzle 411c may supply a different kind of chemical C which is different from a chemical C supplied by the another one of the first nozzle 411a, the second nozzle 411b, or the third nozzle 411c.

A body 442 may fix and support the nozzle 441. The body 442 may be connected to the rotation shaft 443 rotated in the third direction Z by the rotation member 444. When the rotation member 444 rotates the rotation shaft 443, the body 442 may rotate around the third direction Z. Accordingly, an outlet of the nozzle 441 may move between a liquid supply position which is a position where the treating liquid is supplied to the substrate M and a standby position which is a position where the treating liquid is not supplied to the substrate M.

The heating unit 450 may heat the substrate M. The heating unit 450 may heat a partial region of the substrate M. The heating unit 450 may heat a specific region of the substrate M. The heating unit 450 may heat the substrate M on which a liquid film is formed by supplying the chemical C. The heating unit 450 may heat a pattern formed on the substrate M. The heating unit 450 may heat some of the patterns formed on the substrate M. The heating unit 450 may heat any one of the first pattern P1 or the second pattern P2. For example, the heating unit 450 may heat the second pattern P2 among the first pattern P1 and the second pattern P2. In an embodiment, the heating unit 450 may heat the second pattern P2 by irradiating a laser light L with the second pattern P2.

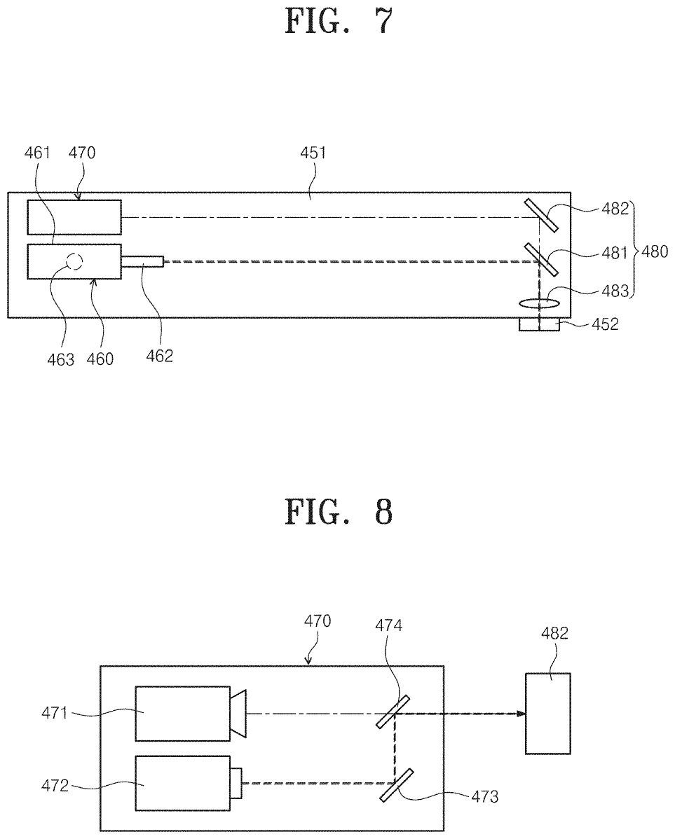

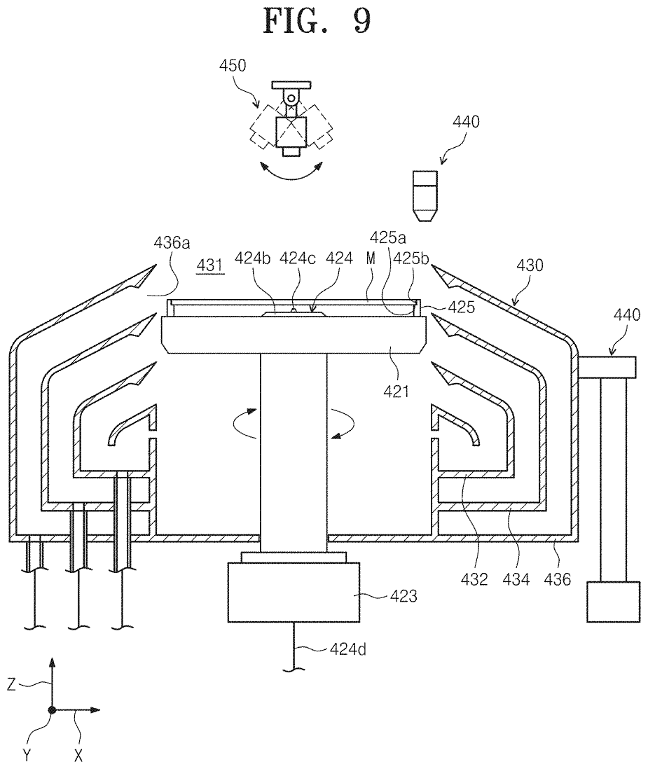

FIG. 7 illustrates a body, a laser module, an image module, and an optical module of a heating unit of FIG. 4. FIG. 8 is a top view of the image module of FIG. 7. Referring to FIG. 7 and FIG. 8, the heating unit 450 may include a body 451, a driver 453, a shaft 454, a moving member 455, a laser module 460, an image module 470, and an optical module 480.

The body 451 may be a container having an installation space therein. The body 451 may be provided with a laser irradiation module 460 to be described later, an image module 470 and an optical module 480. The body 451 may include a laser irradiator 452. The laser light L emitted by the laser irradiation module 460 to be described later may be emitted to the substrate M through the laser irradiator 452. In addition, a light irradiated by the illumination member 472 to be described later may be provided through the laser irradiator 452. In addition, an image imaging of an image acquisition member 471 to be described later may be performed through the laser irradiator 452.

The driver 453 may be a motor. The driver 453 may be connected to the shaft 454. Also, the shaft 454 may be connected to the body 451. The shaft 454 may be connected to the body 451 via the moving member 455. The driver 453 may rotate the shaft 454. When the shaft 454 is rotated, the body 451 may be rotated. Accordingly, a position of the laser irradiator 452 of the body 451 may be changed. For example, the position of the laser irradiator 452 may be changed using a third direction Z as a rotation axis. When viewed from above, a center of the laser irradiator 452 may be moved in an arc form around the shaft 454. When viewed from above, the center of the laser irradiator 452 may be moved to pass through a center of the substrate M supported by the support unit 420.

The laser irradiator 452 may be moved between a heating position irradiating a laser light L to the substrate M and a standby position which is a standby position when a heating is not performed on the substrate M. Also, the driver 453 may move the shaft 454 in an up/down direction. That is, the driver 453 may change the position of the laser irradiator 452 in the up/down direction. In addition, a plurality of drivers 453 may be provided, one of which may be provided as a rotation motor for rotating the shaft 454, and the other may be provided as a linear motor for moving the shaft 454 in an up/down direction.

A moving member 455 may be provided between the shaft 454 and the body 451. The moving member 455 may be an LM guide. The moving member 455 may move the body 451 in a lateral direction. The moving member 455 may move the body 451 along a first direction X and/or a second direction Y.

The position of the laser irradiator 452 of the heating unit 450 may be moved to the heating position and the standby position by the moving member 455 and the driver 453. While the laser irradiator 452 irradiates the laser light L to the substrate M, the position of the laser irradiator 452 is fixed. In an embodiment, the heating position may be a position where the center of the laser irradiator 452 coincides with a center of the support unit 420 when viewed from above. For example, when viewed from above, the laser irradiator 452 may be positioned at a position corresponding to a point A of the substrate M supported on the support unit 420. When the treating liquid is supplied to the liquid supply unit 440 on the substrate M, the laser irradiator 452 is moved to the standby position when the substrate M is taken into the housing (not shown) or the substrate M is taken out of the housing (not shown).

The laser module 460 may include a laser irradiation unit 461, a beam expander 462, and a tilting member 463. The laser irradiation unit 461 may irradiate the laser light L. The laser irradiation unit 461 may irradiate the laser light L to the substrate M supported by the support unit 420. For example, the laser irradiation unit 461 may irradiate the laser light L to the second pattern P2 formed on the substrate M supported by the support unit 420. The laser irradiation unit 461 may emit the laser light L having a straightness. A form/profile of the laser light L emitted by the laser irradiation unit 461 may be adjusted by the beam expander 462. For example, a diameter of the laser light L emitted by the laser irradiation unit 461 may be changed by the beam expander 462. The diameter of the laser light L emitted by the laser irradiation unit 461 may be expanded or reduced by the beam expander 462.

The tilting member 463 may tilt an irradiation direction of the laser light L emitted by the laser irradiation unit 461. For example, the tilting member 463 may rotate the laser irradiation unit 461 based on an axis to tilt the irradiation direction of the laser light L irradiated by the laser irradiation unit 461. The tilting member 463 may include a motor.

The image module 470 may monitor the laser light L emitted by the laser irradiation unit 461. The image module 470 may include an image acquisition member 471, an illumination member 472, a first reflective plate 473, and a second reflective plate 474. The image acquisition member 471 may acquire an image of the substrate M. The image acquisition member 471 may acquire an image including a point at which the laser light L irradiated by the laser irradiation unit 461 is irradiated. The image acquisition member 471 may acquire an image including the second pattern P2 formed on the substrate M. The image acquisition member 471 may be a camera.

The illumination member 472 may provide a light so that an image acquisition of the image acquisition member 471 may be easily performed. A light provided by the illumination member 472 may be sequentially reflected along the first reflective plate 473 and the second reflective plate 474.

The optical module 480 may have a coaxial of an irradiation direction of the laser light L irradiated by the laser irradiation unit 461, an imaging direction in which the image acquisition member 471 acquires an image, and an irradiation direction of a light provided by the illumination member 472 when viewed from above. The illumination member 472 may transmit a light to a region to which the laser light L is irradiated by the optical module 480. In addition, the image acquisition member 471 may acquire an image such as an image/photo for a region to which the laser light L is irradiated in real time. The optical module 480 may include a first reflective member 481, a second reflective member 482, and a lens 483.

The first reflective member 481 may change an irradiation direction of the laser light L emitted by the laser irradiation unit 461. For example, the first reflective member 481 may change the irradiation direction of the laser light L irradiated in a horizontal direction to a vertical downward direction. In addition, a laser light L refracted by the first reflective member 481 may sequentially pass through the lens 483 and the laser irradiator 452, and may be transmitted to a substrate M to be treated.

The second reflective member 482 may change the imaging direction of the image acquisition member 471. For example, the second reflective member 482 may change the imaging direction of the image acquisition member 471 in the horizontal direction to the vertical downward direction. In addition, the second reflective member 482 may change the irradiation direction of light of the illumination member 472 sequentially transmitted through the first reflective plate 473 and the second reflective plate 474 from the horizontal direction to the vertical downward direction.

In addition, the first reflective member 481 and the second reflective member 482 may be provided at the same position when viewed from above. The first reflective member 481 and the second reflective member 422 are may be disposed such that the imaging direction and the laser pathway coincide. In addition, the second reflective member 482 may be disposed above the first reflective member 481. In addition, the first reflective member 481 and the second reflective member 482 may be tilted at the same angle.

The controller 30 may control a substrate treating apparatus. The controller 30 may control the support unit 420 and the heating unit 450. The controller 30 may control a moving stage so that a position of the substrate M positioned on the support unit 420 is changed. The controller 30 may control the moving stage part such that a specific pattern formed on the substrate M is positioned in a specific region. The controller 30 may control the moving stage part so that the second pattern P2 formed on the substrate M is positioned at the center of the laser irradiator 452 which is moved to the heating position when viewed from above. When the controller 30 may control the first driving unit 423 and the second driving unit 424 to move the second pattern P2 to a region including the center of the laser irradiator 452 which is moved to the heating position when viewed from above.

When the substrate M is supported on the support unit 420, the controller 30 can move the moving stage part so that the specific pattern formed on the substrate M is positioned at the specific region. After the substrate M is supported on the support unit 420, the controller 30 may control the moving stage part so that the second pattern P2 is positioned at the heating position before the treating liquid is supplied to the substrate M by the liquid supply unit 440. In an embodiment, the moving stage part may be controlled so that the second pattern P2 is positioned at point A.

The controller 30 may control the rotation part to rotate the support unit 420 while the liquid supply unit 440 supplies the treating liquid to the substrate M after the second pattern P2 is positioned below the heating position. The controller 30 may rotate the support shaft 426 by driving the driving member 427 while supplying a chemical C from the liquid supply unit 440 onto the substrate M. Accordingly, the moving stage part and the chuck 421 may be rotated, and the substrate M may be rotated. After supplying the treating liquid from the liquid supply unit 440 onto the substrate M, the controller 30 may control the rotation part so that a rotation of the support unit 420 is stopped for a set time.

The controller 30 may control a movement of the heating unit 450 so that the laser irradiator 452 of the heating unit 450 moves from the standby position to the heating position after the set time elapses. The controller 30 may control the heating unit 450 to irradiate the laser light L to the second pattern P2 positioned at the heating position. The controller 30 may control the rotation part to stop the rotation of the support unit 420 while irradiating the laser light L to the second pattern P2.

The second pattern P2 may be formed at any region on the substrate M. A position of the second pattern P2 formed in an arbitrary region on the substrate M is different for each substrate M taken into the substrate treating apparatus. A position of the heating unit 450 should be necessarily changed to irradiate the laser light at each process with respect to the second pattern P2 formed at each substrate M disposed at different regions. In this case, a position information of the second pattern P2 should be acquired for each substrate M, and the heating unit 450 should be moved to a top position corresponding to the second pattern P2 based on an acquired position information. Accordingly, when a fine error occurs in the position information of the second pattern P2 or in a movement amount of the heating unit 450, it is difficult to accurately etch the second pattern P2. Accordingly, an error occurs between a critical dimension of the first pattern P1 and between a critical dimension the second pattern P2.

According to an embodiment of the inventive concept described above, the heating position which is a specific region to which the laser light L is irradiated may be set at the heating unit 450, and the heating unit 450 may irradiate the laser light L onto the substrate M only at the heating position which is fixed. In addition, the second pattern P2, which may be formed at different positions for each substrate M, may be moved to the heating position, which is the specific region to which the laser light L is irradiated, and the laser light L may be irradiated toward the second pattern P2 moved to the heating position. That is, the chuck 421 supporting the substrate M on which the second pattern P2 is formed may use the moving stage part to position the second pattern P2 at the heating position. Accordingly, even though the second pattern P2 is formed at different regions for each substrate M, the laser light L may be irradiated only at a specific position to perform a precise etching with respect to the second pattern P2.

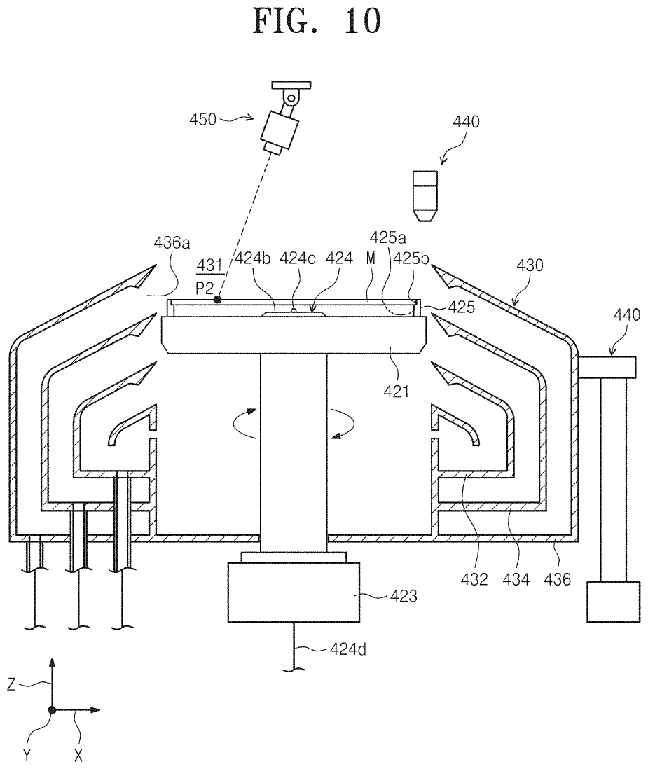

FIG. 9 schematically illustrates another embodiment of a liquid treating chamber of FIG. 2. Hereinafter, the liquid treating chamber according to another embodiment of the inventive concept will be described with reference to FIG. 9. Since a description of the liquid treating chamber according to another embodiment is similar to the description of the liquid treating chamber according to the above-described embodiment except for a case in which the description thereof is additionally described, a description thereof will be omitted.

The liquid treating chamber according to an embodiment of the inventive concept may include a housing (not shown), a support unit 420, a treating container 430, a liquid supply unit 440, and a heating unit 450.

The support unit 420 may support a substrate M. The support unit 420 may rotate the substrate M. The support unit 420 may support and rotate the substrate M at a treating space of the treating container 430 to be described later. The support unit 420 may include a chuck 421, a support pin 422, a support shaft 426, and a driving member 427.

The chuck 421 may have a plate form having a constant thickness. The chuck 421 may have a top surface provided in a generally circular shape when viewed from above. The top surface of the chuck 421 may be provided to have an area larger than that of the substrate M. A support pin 422 may be installed on the chuck 421.

The support pin 422 may support the substrate M. When viewed from above, the support pin 422 may have a substantially circular shape. When viewed from above, the support pin 422 may have a shape in which a portion corresponding to a corner region of the substrate M is downwardly recessed. The support pin 422 may have a first surface and a second surface. In an embodiment, the first surface may support a bottom portion of the corner region of the substrate M. The second surface may face a side part of an edge region of the substrate M so as to limit a movement of the substrate M in a lateral direction when the substrate M is rotated. At least one support pin 422 may be provided. In an embodiment, a plurality of support pins 422 may be provided. The support pins 422 may be provided in a number corresponding to the number of corner regions of the substrate M having a rectangular shape. The support pin 422 may support the substrate M to be spaced apart from a bottom surface of the substrate M and the top surface of the chuck 421.

The support shaft 426 may be coupled to the chuck 421. The support shaft 426 may be positioned below the chuck 421. The support shaft 426 may be a hollow shaft. The support shaft 426 may be rotated by the driving member 427. The driving member 427 may be a hollow motor. When the driving member 427 rotates the support shaft 426, the chuck 421 coupled to the support shaft 426 may rotate. A substrate M placed on the support pin 422 which is installed on the chuck 421 may be rotated together with a rotation of the chuck 421.

The heating unit according to an embodiment of the inventive concept is provided mostly similar to the heating unit according to the embodiment of the inventive concept described with reference to FIG. 7 and FIG. 8, except for the driver 453, the shaft 454, and the moving member 455, and thus repeated descriptions thereof will be omitted.

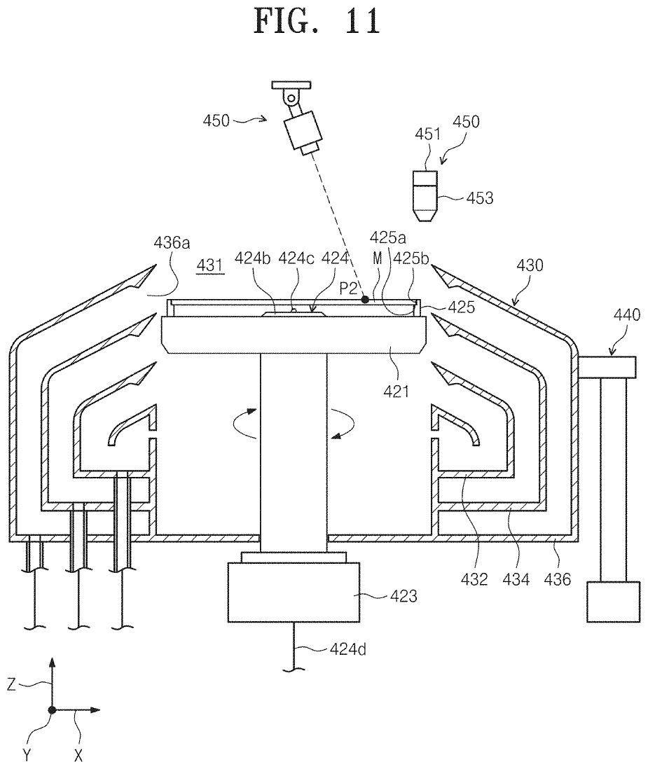

FIG. 10 and FIG. 11 schematically illustrate a state of irradiating a light to a substrate at a heating unit of FIG. 9. Referring to FIG. 10 and FIG. 11, the heating unit 450 according to an embodiment of the inventive concept may be positioned above the support unit 420. The heating unit 450 may be fixedly installed above the support unit 420. The heating unit 450 may be fixedly installed on a top wall of a housing (not shown). When viewed from above, the heating unit 450 may be fixedly installed at a position corresponding to a center of the substrate M supported on the support unit 420. The heating unit 450 may be fixed to a top wall of the housing (not shown) by a fixing member (not shown) and tilted based on an axis installed at the fixing member. A tilting with respect to the heating unit 450 may be performed by providing a motor. An angle at which the heating unit 450 is tilted may be an angle corresponding to an angle from a center of the substrate M supported on the support unit 420 to an outer surface. Accordingly, an irradiation direction of the laser light L irradiated by the heating unit 450 may be tilted.

A controller 30 may control the heating unit 450. The controller 30 may control a tilting angle of the heating unit 450. In an embodiment, when the support unit 420 is viewed from the front as shown in FIG. 10, when the second pattern P2 is formed on a left side of the substrate

M with respect to the support shaft 426, the controller 30 may control the heating unit 450 to be tilted to the left side of the substrate M on which the second pattern P2 is formed. As another example, when the support unit 420 is viewed from the front as shown in FIG. 11, when the second pattern P2 is formed on a right side of the substrate M with respect to the support shaft 426, the controller 30 may control the heating unit 450 to be tilted to the left side of the substrate M on which the second pattern P2 is formed. The controller 30 may expand or reduce a diameter of the laser light L at a beam expander 462 according to an angle at which the heating unit 450 is tilted.

Hereinafter, a substrate treating method according to an embodiment of the inventive concept will be described in detail. The substrate treating method described below may be performed by the liquid treating chamber 400 described above. Also, the controller 30 can control components of the liquid treating chamber 400 so that the liquid treating chamber 400 can perform the substrate treating method described below. For example, the controller 30 may generate a control signal for controlling at least one of a support unit 420, a lifting/lowering member 436, a liquid supply unit 440, and a heating unit 450 so that the components of the liquid treating chamber 400 may perform the substrate treating method described below.

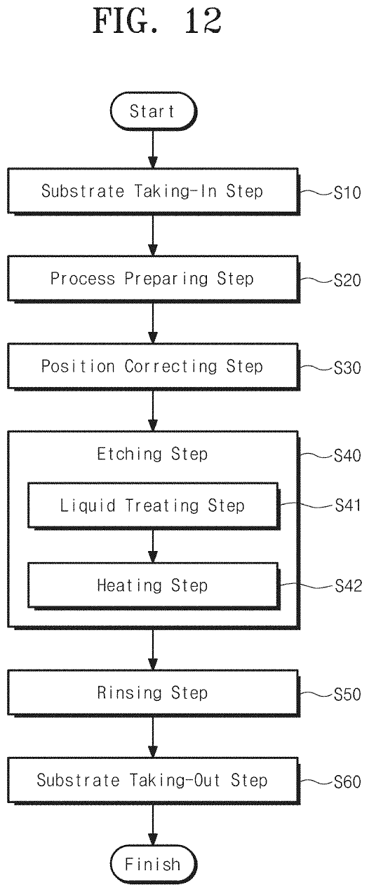

FIG. 12 is a flowchart illustrating a substrate treating method according to an embodiment of the inventive concept. Referring to FIG. 12, the substrate treating method according to an embodiment of the inventive concept may include a substrate taking-in step S10, a process preparing step S20, a position correcting step S30, an etching step S40, a rinsing step S50, and a substrate taking-out step S60.

In the substrate taking-in step S10, a door may open a taking-in/out port formed at the housing (not shown). In addition, in the substrate taking-in step S10, the transfer robot 320 may seat a substrate M on a support unit 420. While the transfer robot 320 seats the substrate M on the support unit 420, a lifting/lowering member 436 may lower a position of a treating container 430.

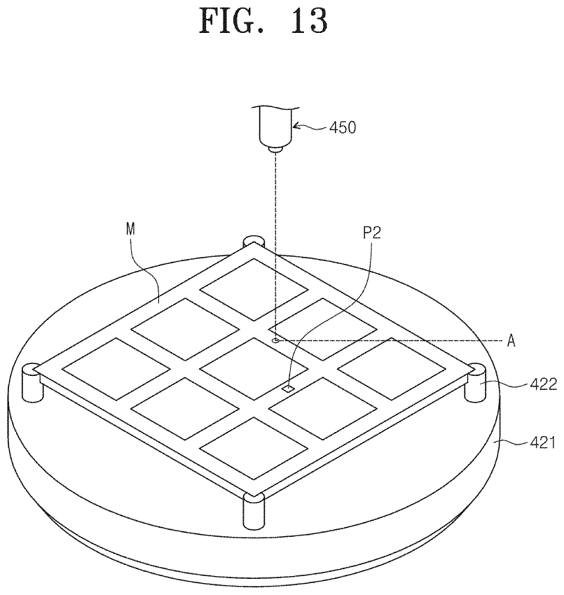

FIG. 13 illustrates a state in which a substrate treating apparatus performs a process preparing step of FIG. 12. Referring to FIG. 13, the process preparing step S20 may be performed after a taking-in of a substrate M is completed. In the process preparing step S20, it may be confirmed whether the substrate M is accurately seated on a support pin 422. In the process preparing step S20, a position of the substrate M may be confirmed. In the process preparing step S20, a position information of patterns formed on the substrate M may be acquired. In the process preparing step S20, a position of a second pattern P2 formed on the substrate M may be confirmed. In the process preparing step S20, an information of the position of the second pattern P2 formed on the substrate M and a heating position A at which the laser light L is irradiated may be collected.

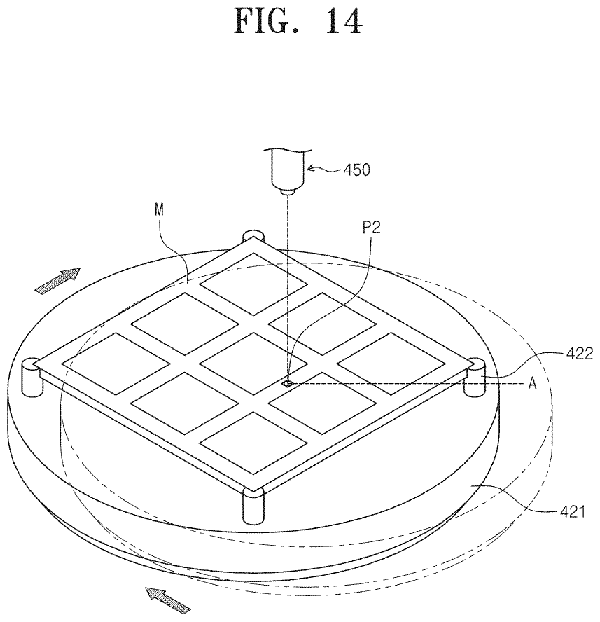

FIG. 14 illustrates a state of a substrate treating apparatus for performing a position correcting step of FIG. 12. Referring to FIG. 14, the position correcting step S30 is a step of changing a position of a substrate M supported on the support unit 420. The position correcting step S30 may change a position of a second pattern P2 formed on the substrate M. The position correcting step S30 may move the support unit 420 to change the position of the second pattern P2. According to an embodiment, in the position correcting step S30, the first driving unit 423 included in the moving stage part may move in a first direction X. In addition, in the position correcting step S30, the second driving unit 424 included in the moving stage part may move in a second direction Y. The chuck 421 may move in the first direction X and the second direction Y by the first driving unit 423 and the second driving unit 424. In the position correcting step S30, the support unit 420 is moved in the first direction X and the second direction Y so that the second pattern P2 is positioned at the heating position A. In the position correcting step S30, the second pattern P2 is moved to the heating position A based on a position information of the second pattern P2 formed on the substrate M which is collected in the process preparing step S20.

In an etching step S40, an etching on a pattern formed on the substrate M may be performed. In the etching step S40, an etching with respect to the pattern formed on the substrate M can be carried out so that a critical dimension of the first pattern P1 and a critical dimension of the second pattern P2 coincide with each other. The etching step S40 may be a critical dimension correction process for correcting a critical dimension difference between the first pattern P1 and the second pattern P2 described above. The etching step S40 may include a liquid treating step S41 and a heating step S42.

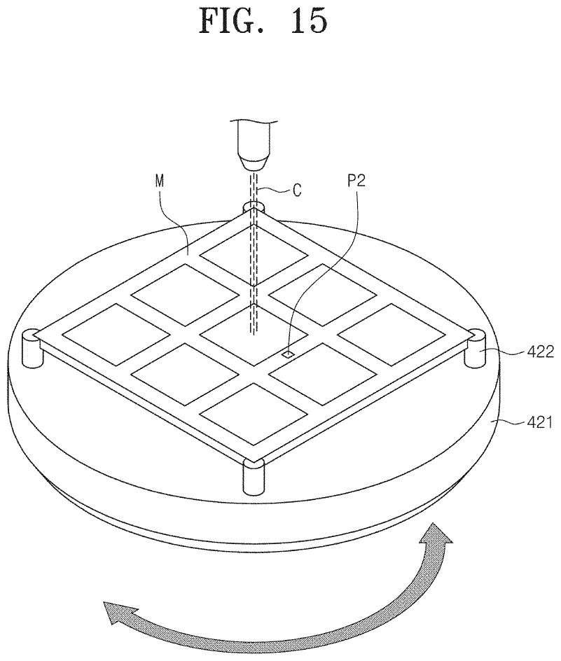

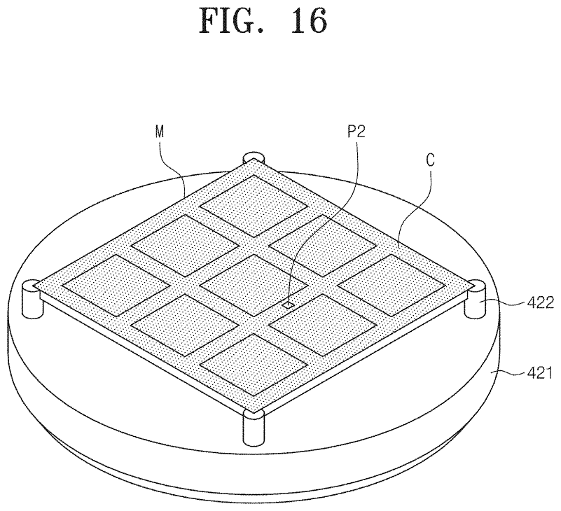

FIG. 15 illustrates a state of a substrate treating apparatus for performing a liquid treating step of FIG. 12. FIG. 16 illustrates a state of the substrate treating apparatus at which a liquid supply has been completed at the liquid treating step.

Referring to FIG. 15 and FIG. 16, the liquid treating step S41 may be a step in which a liquid supply unit 440 supplies an etchant which is a chemical C to a substrate M as illustrated in FIG. 15. In the liquid treating step S41, a support unit 420 may rotate the substrate M. However, the inventive concept is not limited thereto, and in the liquid treating step S41, the support unit 420 may not rotate the substrate M. An amount of the chemical C supplied at the liquid treating step S41 may be supplied enough to form a puddle of the chemical C supplied onto the substrate M. For example, the amount of the chemical C supplied at the liquid treating step S41 may cover an entire top surface of the substrate M, but may be supplied to a degree that the amount of the chemical C does not flow down or is not large even when if chemical C flows down from the substrate M. If necessary, the etchant may be supplied to an entire top surface of the substrate M while a nozzle 441 changes its position.

As illustrated in FIG. 16, after the liquid supply unit 440 supplies the chemical C to the substrate M, the support unit 420 may not rotate. The support unit 420 may stop to form a puddle of the chemical C supplied onto the substrate M.

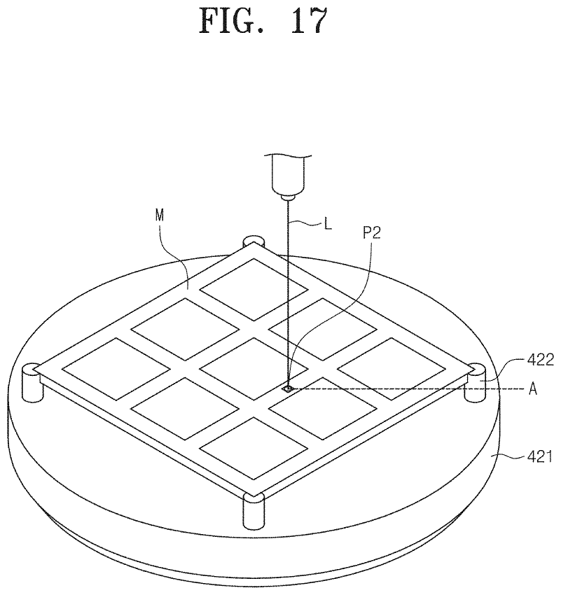

FIG. 17 illustrates a state of a substrate treating apparatus for performing a heating step of FIG. 12. Referring to FIG. 17, in the heating step S42, a heating unit 450 may be moved from a standby position to a heating position A. At the heating step S42 a center of the laser irradiator 452 of the heating unit 450 may move to above of the heating position A. At the heating step S42, a substrate M may be heated by irradiating a laser light L to the substrate M. In the heating step S42, a heating module 460 can heat a substrate M on which a liquid film is formed by irradiating the laser light L to the substrate M. In the heating step S42, the laser light L may be irradiated to a specific region of the substrate M. A temperature of the specific region to which the laser light L is irradiated may be increased. Accordingly, an etching degree by the chemical C of a region to which the laser light L is irradiated may increase. In addition, in the heating step S42, the laser light L may be irradiated to any one of the first pattern P1 or the second pattern P2. For example, the laser light L may be emitted only to the second pattern P2 among the first pattern P1 and the second pattern P2. At the heating step S42, the laser light L may be irradiated to the second pattern P2 moved to the heating position A.

Accordingly, an etching ability of the chemical C with respect to the second pattern P2 is improved. Accordingly, a critical dimension of the first pattern P1 may be changed from a first width (e.g., 69 nm) to a target critical dimension (e.g., 70 nm). Also, a critical dimension of the second pattern P2 may be changed from a second width (e.g., 68.5 nm) to the target critical dimension (e.g., 70 nm). That is, it is possible to minimize a critical dimension deviation of a pattern formed on the substrate M by improving the etching ability with respect to some regions of the substrate M.

The heating position A, which is a specific region to which the laser light L is irradiated, is set at the heating unit 450, and the heating unit 450 may irradiate the laser light L onto the substrate M only at the heating position A which has been specified. In addition, the second pattern P2, which may be formed at different positions for each substrate M, may be moved to the heating position A, which is the specific region to which the laser light L is irradiated, and the laser light L may be irradiated toward the second pattern P2 moved to the heating position A. That is, the chuck 421 supporting the substrate M at which the second pattern P2 is formed may be used to position the second pattern P2 at the heating position A by utilizing the moving stage part. Accordingly, even though the second pattern P2 is formed in different regions for each substrate M, the laser light L may be irradiated only at the specific position to perform a precise etching with respect to the second pattern P2.

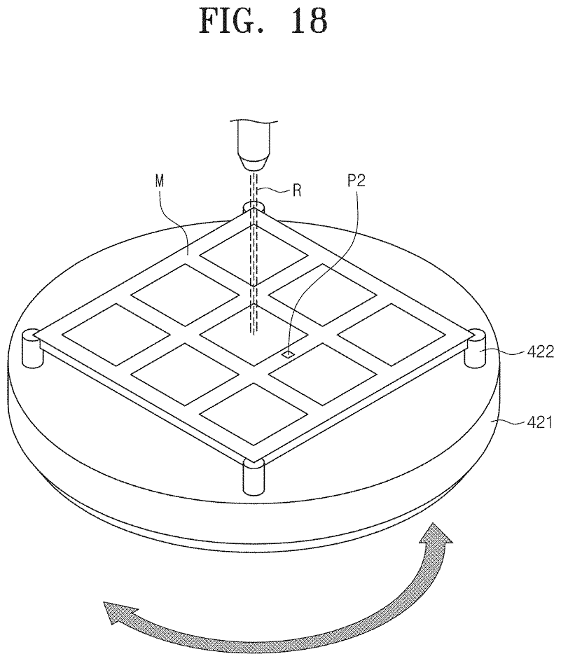

FIG. 18 illustrates a state of a substrate treating apparatus performing a rinsing step of FIG. 12. Referring to FIG. 18, in the rinsing step S50, process by-products generated in the etching step S40 may be removed from the substrate M. In the rinsing step S50, a rinsing liquid R may be supplied to a rotating substrate M to remove process by-products formed on the substrate M. In order to dry a rinsing liquid R remaining on the substrate M as necessary, the support unit 420 may rotate the substrate M at a high speed to remove the rinsing liquid R remaining on the substrate M.

In the substrate taking-out step S60, a substrate M which has been treated may be taken out from an inner space inside of the housing (not shown). In the substrate taking-out step S60, a door may open a taking-in/out port formed at the housing (not shown). In addition, in the substrate taking-out step S60, a transfer robot 320 may unload the substrate M from the support unit 420 and take an unloaded substrate M out of the inner space 412 inside of the housing (not shown).

In the embodiment of the inventive concept described above, an etching rate of the second pattern P2 is improved at the substrate M having the first pattern P1 which is a monitoring pattern for monitoring an exposing pattern and the second pattern P2 which is a condition setting pattern for treating the substrate. However, unlike this, functions of the first pattern P1 and the second pattern P2 may be different from those of the above-described embodiment of the inventive concept. In addition, according to an embodiment of the inventive concept, only one of the first pattern P1 or the second pattern P2 is provided, and an etching rate of one of the first pattern P1 or the second pattern P2 may be improved. In addition, according to an embodiment of the inventive concept, the same may be applied to improve an etching rate of a specific region on a substrate such as a wafer or a glass other than a photomask.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A mask treating apparatus comprising:
a support unit configured to support and rotate a mask, the mask having a first pattern within a plurality of cells thereof and a second pattern outside regions of the plurality of cells; and
a heating unit having a laser irradiator for irradiating a laser light to a specific region of the mask supported on the support unit, and
a controller configured to control the support unit and the heating unit, and
wherein the support unit comprises:
a support part for supporting the mask; and
a moving stage part configured to move a position of the support part, and wherein the controller controls the moving stage part so a position of the mask supported on the support part is changed so the second pattern is positioned at the specific region.

2. The mask treating apparatus of claim 1, wherein the support unit further comprises a rotation part configured to rotate the moving stage part, and wherein the controller controls the rotation part so the mask stop rotation while the laser light is being irradiated by the laser irradiator to the second pattern.

3. The mask treating apparatus of claim 2 further comprising a liquid supply unit configured to supply a treating liquid to the mask supported on the support unit, and
wherein the controller controls the rotation part so the mask is rotated while the liquid supply unit is supplying the treating liquid to the mask.

4. The mask treating apparatus of claim 1, wherein the moving stage part comprises:
a base positioned below the support part;
a first driving part installed at the base and moving the support part in a first direction which is horizontal to the ground; and
a second driving part installed at the base and moving the support part in a second direction which is orthogonal to the first direction and horizontal to the ground.

5. The mask treating apparatus of claim 3 further comprising a container having a treating space for treating the mask and a recollecting path for recollecting the treating liquid, and
wherein the support unit supports the substrate at the treating space.

6. The mask treating apparatus of claim 1, wherein a position of the laser irradiator is fixed while the laser irradiator irradiates the laser light.

7. The mask treating apparatus of claim 1, wherein a process for minimizing a deviation between a critical dimension of the first pattern and a critical dimension of the second pattern by irradiating the laser light with respect to the second pattern is performed.

8. The mask treating apparatus of claim 1, wherein regarding a first pattern and a second pattern provided at each cell, the first pattern is a monitoring pattern of an exposing pattern formed at a cell and the second pattern is a condition setting pattern of the mask treating apparatus.

9. A substrate treating apparatus comprising:
a support unit configured to support and rotate a substrate at which a pattern is formed;
a heating unit configured to heat a specific region of the substrate;
a controller configured to control the support unit and the heating unit, and
wherein the support unit comprises:
a support part for supporting the substrate; and
a moving stage part configured to change a position of the support part, and
wherein the controller controls the moving state unit so a position of the substrate supported on the support unit is changed so a specific pattern among the pattern is positioned at the specific region.

10. The substrate treating apparatus of claim 9, wherein the support unit further comprises a rotation part configured to rotate the moving stage part, and
wherein the controller controls the rotation part so the substrate does not rotate while the heating unit heats the specific pattern.

11. The substrate treating apparatus of claim 10 further comprising a liquid supply unit for supplying a treating liquid to the substrate supported on the support unit, and
wherein the controller controls the rotation part so the substrate is rotated while the liquid supply unit is supplying the treating liquid to the substrate.

12. The substrate treating apparatus of claim 9, wherein the moving stage part comprises:
a base positioned below the support part;
a first driving part installed at the base and moving the support part in a first direction which is horizontal to the ground; and
a second driving part installed at the base and moving the support part in a second direction which is orthogonal to the first direction and horizontal to the ground.

13. The substrate treating apparatus of claim 9, wherein the heating unit includes a laser irradiator irradiating a laser light to the specific pattern, and a position of the laser irradiator is fixed while the laser irradiator irradiates the laser light.

14. The substrate treating apparatus of claim 13, wherein a process for minimizing a deviation between a critical dimension of the specific pattern and a critical dimension of a pattern aside from the specific pattern by irradiating the laser light with respect to the specific pattern is performed.

15. The substrate treating apparatus of claim 14, wherein the specific pattern is a condition setting pattern of the substrate treating apparatus.

16-20. (canceled)
